(19) United States
(12) Patent Application Publication
(10) Pub. No.: US 2024/0379322 A1
(43) Pub. Date: Nov. 14, 2024

(54) MULTI-BEAM SYSTEM AND MULTI-BEAM GENERATING UNIT WITH REDUCED SENSITIVITY TO DRIFT AND DAMAGES

(71) Applicant: Carl Zeiss MultiSEM GmbH, Oberkochen (DE)

(72) Inventors: Alexander Wertz, Aalen (DE); Christof Riedesel, Aalen (DE); Ralf Lenke, Lauchheim (DE); Yanko Sarov, Aalen (DE); Ulrich Bihr, Dirgenheim (DE); Michael Kelp, Gerstetten (DE); Marcus Kaestner, Syrgenstein-Staufen (DE); Georg Kurij, Ulm (DE); Dieter Schumacher, Heidenheim (DE)

(21) Appl. No.: 18/782,169

(22) Filed: Jul. 24, 2024

Related U.S. Application Data
(63) Continuation of application No. PCT/EP2023/025014, filed on Jan. 18, 2023.

(30) Foreign Application Priority Data
Jan. 31, 2022 (DE) 10 2022 201 005.1

(51) Int. Cl. H01J 37/09; H01J 37/12; H01J 37/28

(52) U.S. Cl. CPC H01J 37/09; H01J 37/12; H01J 37/28; H01J 2237/002; H01J 2237/0455; H01J 2237/1205

(57) ABSTRACT

A multi-beam generating unit of a multi-beam charged particle imaging system can exhibit reduced sensitivity to drift and extended lifetime. Drifts due to x-ray irradiation and thermal loads can be minimized by a combination of at least one of a shielding element, a cooling member, or an architecture and method for operating an active multi-aperture element. A lifetime can be improved by annealing methods of an active multi-aperture element or a microelectronic device forming for example a voltage supply unit.

### CROSS-REFERENCE TO RELATED APPLICATIONS

The present application is a continuation of, and claims benefit under 35 USC 120 to, international application No. PCT/EP2023/025014, filed Jan. 18, 2023, which claims benefit under 35 USC 119 of German Application No. 10 2022 201 005.1, filed Jan. 31, 2022. The entire disclosure of each of these applications is incorporated by reference herein.

### FIELD

The disclosure relates to a multi-beam generating unit with an array of micro-lenses or multi-pole elements of a multi-beam charged particle imaging system.

### BACKGROUND

WO 2005/024881 A2 discloses an electron microscope system which operates with a multiplicity of electron beamlets for the parallel scanning of an object to be inspected with a plurality of electron beamlets. Multiple beamlets for a multi-beam, charged particle microscope are generated in a multi-beam generating unit. The plurality of electron beamlets is generated by directing a primary electron beam onto the multi-beam generating unit. The multi-beam generating unit comprises a first multi-aperture element, which has a multiplicity of openings. One portion of the electrons of the electron beam is incident onto the multi-aperture element and is absorbed there, and another portion of the beam transmits the openings of the multi-aperture element and thereby downstream of each opening an electron beamlet is formed whose cross section is defined by the cross section of the opening. Furthermore, suitably selected electric fields which are provided in the beam path upstream and/or downstream of the multi-aperture element cause each opening in the multi-aperture element to act as a lens on the electron beamlets passing the opening so that the each electron beamlet is focused into a surface which lies at a distance from the multi-aperture element. The surface in which the foci of the electron beamlets are formed is imaged by downstream optics onto the surface of the object or sample to be inspected. The primary electron beamlets trigger secondary electrons or backscattered electrons to emanate as secondary electron beamlets from the object, which are collected and imaged onto a detector. Each of the secondary beamlets is incident onto a separate detector element so that the secondary electron intensities detected therewith provide information relating to the sample at the location where the corresponding primary beamlet is incident onto the sample. The plurality of primary beamlets is scanned systematically over the surface of the sample and an electron microscopic image of the sample is generated in the usual way for scanning electron microscopes. The resolution of a scanning electron microscope is generally limited by the focus diameter of the primary beamlets incident onto the object. Consequently, it is desirable in multi-beam electron microscopy for all the beamlets to form the same small focus points on the object.

It is understood that the system and method illustrated in WO 2005/024881 at the example of electrons can be very well applicable in general to charged particles.

Multi-beam charged particle microscopes commonly use both micro-optical array elements and macroscopic elements in a charged particle projection system. The multi-beam generating units comprise elements for splitting, partially absorbing, and influencing a beam of charged particles. As a result, a plurality of beamlets of charged particles in a predefined raster configuration is generated. Multi-beam generating units comprise micro-optical elements, such as the first multi-aperture element, further multi-aperture elements and micro-optical deflection elements or multi-pole array elements.

The multi-beam generating unit includes a first multi-aperture element with a plurality of apertures. A primary electron beam impinges on the first multi-aperture element, and some of the electrons pass the apertures and form the plurality of beamlets. A major part, however, is absorbed at the surface of the first multi-aperture element. From the electrons passing the apertures, on the other hand, the plurality of primary charged particle beamlets is formed. For this task, an array-optical element, for example a multi-pole or multi-stigmator array or a lens array are arranged downstream of a first multi-aperture element. The array-optical elements are provided with a plurality of apertures, each provided with at least one electrode or coil for individually or jointly influencing each primary electron beamlet. It has been observed that during their operation, a multi-stigmator array or a lens array can be subject to drifts in the performance of the array-optical element.

The drifts in the performance of the array-optical element can have several reasons. One reason is drifts of the drivers of an array-optical element. For example, a multi-stigmator array for a plurality of about 100 beamlets can have eight or twelve electrodes per beamlet, adding up to more than 1000 electrodes, which are controlled individually by a plurality of voltage supply units, which can be formed by micro-electronic devices. Therefore, the control architecture for the plurality of multi-pole electrodes of an array-optical element comprises several micro-electronic devices in parallel. The micro-electronic devices provide a plurality of predetermined voltages to the plurality of electrodes or predetermined currents to the plurality of coils. Drifts in the voltages or currents can arise from thermal drifts, from charging effects of the micro-electronic devices, or from local damages generated for example by x-ray radiation. Drifts can be irreversible damages and lead to a failure of a driver of an electrode of a multi-pole element.

A cause for the drift of micro-electronic devices can be scattered or absorbed primary electrons. A small part of the impinging electrons is absorbed or scattered in the apertures, for example at the electrodes, leading to a charging effect and a local change of voltage.

A reason for drift can be a secondary radiation, generated by the absorbed primary electrons at the first multi-aperture element. Secondary radiation comprises secondary electrons and electromagnetic radiation, including x-rays or gamma radiation. Typically, the voltage supply units or micro-electronic devices to control array-optical elements are arranged in the vicinity or periphery of the array-optical elements and may be penetrated or may absorb secondary radiation. It has been observed that secondary radiation can generate a charging effect and eventually a damage to micro-electronic devices.

A reason for drift can be the power, by which an individual micro-electronic device is driven, which can lead to a high thermal load.

The secondary radiation is absorbed in absorption layer or bulk material of the first multi-aperture element only to a small part. In US 2019/0051494 A1 it is proposed to add an additional, second multi-aperture element. However, a second multi-aperture element of sufficient thickness has a plurality of apertures for the plurality of primary charged beamlets generated by the first multi-aperture element. A thick plate can increase the amount of scattered charged particles and can have a negative impact of the plurality of primary beamlets generated at the first multi-aperture element. In modern designs of beam generators with a large number of primary beamlets plurality, it may not be possible to provide a multi-aperture element provided with sufficient thickness to sufficiently block all x-rays generated. In addition, in general, the secondary radiation is not directed and is generated in all directions, including the plurality of apertures. X-ray may pass the second multi-aperture element and may still cause charging effects to electron-optical elements downstream of the first and second multi-aperture element. Furthermore, drifts in the micro-electronic devices can also be produced by other reasons described above.

US 2017/0133194 A1 discloses a particle beam system comprising a particle source; a first multi-aperture plate with a multiplicity of openings downstream of which particle beams are formed; a second multi-aperture plate with a multiplicity of openings which are penetrated by the particle beams; an aperture plate with an opening which is penetrated by all the particles which also penetrate the openings in the first and the second multi-aperture plate; a third multi-aperture plate with a multiplicity of openings which are penetrated by the particle beams, and with a multiplicity of field generators which respectively provide a dipole field or quadrupole field for a beam; and a controller for feeding electric potentials to the multi-aperture plates and the aperture plate so that the second openings in the second multi-aperture plate respectively act as a lens on the particle beams and feed adjustable excitations to the field generators. The controller itself is provided outside the vacuum envelope of the system. The controller is connected via a data link to an electronic circuit for generating adjustable voltages to be provided to the field generators or electrodes. The data link is led through a seal in the vacuum envelope. The electronic circuit is thus provided inside the vacuum chamber and is not shielded against secondary radiation, for example against X-rays being generated inside the vacuum chamber.

### SUMMARY

The present disclosure seeks to provide a charged particle beam system which operates with a multiplicity of charged particle beams and can be used to achieve relatively high imaging performance, such as a better resolution and narrower range of resolution for each beamlet of the plurality of beamlets.

The present disclosure seeks to provide a beam generator for a multi-beam charged particle system with a reduced impact of drifts such as thermal drifts of charging effects. The disclosure seeks to provide a driver with a reduced impact of drifts or damages for a beam generator for a multi-beam charged particle system. The disclosure seeks to provide a method of operation of a beam generator for a multi-beam charged particle system with a reduced impact of drifts such as thermal drifts of charging effects. The disclosure seeks to provide a shielding of secondary radiation such as X-rays.

The disclosure provides an architecture of a multi-beam generating unit of a multi-beam charged particle imaging system with reduced sensitivity to drift and extended lifetime. With the architecture, drifts due to x-ray irradiation and thermal loads are minimized by a combination of at least one member of the group comprising a shielding element, a cooling member, or a method for operating an active multi-aperture element. A lifetime can be improved by annealing methods of an active multi-aperture element or a microelectronic device forming for example a voltage supply unit.

In a first embodiment, a multi-beam system with a plurality of J primary charged particle beamlets, configured for a method of operation of an active multi-aperture element is provided. The multi-beam system comprises at least one active multi-aperture element and a control unit, configured for controlling the active multi-aperture element. An active multi-aperture element comprises a plurality of J apertures arranged in a raster configuration, which are configured for transmitting during use the first plurality of J primary charged particle beamlets through the active multi-aperture element. The raster configuration can be a hexagonal or a rectangular raster of J apertures, or the apertures can be arranged on a series of circular rings. An active multi-aperture element further comprises a plurality of electrodes comprising at least one electrode arranged in the circumference of each of the apertures. According to the first embodiment, the plurality of electrodes comprises at least a first group of electrodes and a second group of electrodes. The multi-beam system further comprises a first voltage supply unit configured to provide during use a plurality of voltages to the first group of electrodes and a second voltage supply unit configured to provide during use a plurality of voltages to the second group of electrodes. The first and second voltage supply unit can be a part of the active multi-aperture element. The first and the second voltage supply units are connected to the control unit. The control unit is configured to control during use a plurality of voltages provided by the first and second voltage supply units to the first and second group of electrodes. The control can for example be achieved via an image quality monitor or via a voltage drift monitor.

In the latter example, the multi-beam system further comprises a monitoring device connected to at least the first voltage supply unit. With the monitoring device, a drift of the first voltage supply unit can be monitored during use.

The control unit is further configured to compensate during use a drift of at least the first voltage supply unit. In an example, the control unit is configured to compensate during use the drift of a first voltage supply unit by a compensating control signal provided to the second voltage supply unit.

The first group of electrodes and the second group of electrodes can be arranged in different angular segments of the raster configuration of the plurality of J apertures. In an alternative example, the first group of electrodes and the second group of electrodes can be arranged in different radial segments of the raster configuration.

The active multi-aperture element can be a micro lens array with a single ring electrode at each of the plurality of aperture. The active multi-aperture element can also be a multi-pole array comprising a plurality of multi-pole elements with a number of K electrodes arranged in the circumference of each of the plurality of apertures, the number K of electrodes of each multi-pole element is two, four, six, eight or twelve.

According to an example of the first embodiment, the multi-beam system further comprises a shielding member. The shielding member is arranged and configured to shield secondary radiation from hitting the first and second voltage supply units. Secondary radiation can be x-ray radiation or secondary electrons, which lead to charging effects or damages at the voltage supply units. In an example, a first shielding member is arranged at the beam entrance side of a primary multi-beamlet forming unit and configured with a large aperture. The charged particle beam from a particle beam source is filtered by the large aperture and a beam with a diameter and shape of the raster configuration is generated. Thereby, secondary radiation generated in the multi-aperture plates of the primary multi-beamlet forming unit can be reduced. Furthermore, with the large aperture, the first shielding member can be configured with sufficient thickness of a material composition comprising high density materials, such that secondary radiation generated in the first shielding member cannot penetrate the primary multi-beamlet forming unit below.

In an example, an active multi-aperture element comprises an outer or peripheral zone, where the at least first and second voltage supply units are arranged, and an inner or membrane zone with the plurality of J apertures. In this example, a second shielding member can be provided between an outer or peripheral zone and the membrane zone.

In an example, at least a first voltage supply unit is arranged in a space between the plurality of J apertures, and the shielding member is formed as a cap covering the first voltage supply unit.

According to an example of the first embodiment, an active multi-aperture element for a multi-beam system is provided. The active multi-aperture element comprises a base plate with an inner membrane zone with a plurality of J apertures arranged in a raster configuration. Thereby, the active multi-aperture element is configured for transmitting during use a plurality of J primary charged particle beamlets. The active multi-aperture element further comprises a plurality of J multi-pole elements, each multi-pole element comprises one aperture of the plurality of J apertures, and each multi-pole element comprises K electrodes, and each multi-pole element is configured to influence one of the primary charged particle beamlets.

The active multi-aperture element can further comprise a plurality of L voltage supply units, the plurality of L voltage supply units is arranged on the base plate. According to this example, each of the K electrodes of one multi-pole element is connected to only one of the plurality of L voltage supply units. For example, a first plurality of J multi-pole elements comprises at least a first group of multi-pole elements and a second group of multi-pole elements. The electrodes of the first group of multi-pole elements is connected to a first voltage supply unit and the second group of multi-pole elements is connected to a second voltage supply unit. The first group of multi-pole elements and the second group of multi-pole elements can be arranged in different annular or ring segments of the raster configuration or in different angular segments of the raster configuration. The active multi-aperture element of an example comprises a second plurality of J multi-pole elements arranged downstream of first plurality multi-pole elements, each multi-pole element comprising a plurality of K2 electrodes, wherein each of the K2 electrodes of one multi-pole element of the second plurality of J multi-pole elements is connected to only one of the plurality of L voltage supply units. In a further example, each of the K1 electrodes of one multi-pole element of the first plurality of J multi-pole elements and each of the K2 electrodes of the corresponding multi-pole element of the second plurality of J multi-pole elements is connected to the same voltage supply unit.

In a second embodiment, a multi-beam system with at least one shielding member or a cooling member is provided. A primary multi-beamlet forming unit for a multi-beam system comprises an active multi-aperture element. The active multi-aperture element comprises a plurality of J apertures arranged in a raster configuration, configured for transmitting during use a first plurality of J primary charged particle beamlets through the active multi-aperture element. The active multi-aperture element further comprises a plurality of electrodes comprising at least one electrode arranged in the circumference of each of the apertures and at least a first voltage supply unit configured to provide a plurality of voltages to a group of electrodes of the plurality of electrodes. The primary multi-beamlet forming unit for a multi-beam system according to the second embodiment further comprises at least a shielding member provided to shield secondary radiation from hitting the first voltage supply unit.

In an example, a first shielding member is arranged at the beam entrance side of a primary multi-beamlet forming unit and configured with a large aperture. With the large aperture, the first shielding member can be configured with sufficient thickness of a material composition comprising high density materials, such that secondary radiation generated in the first shielding member cannot penetrate the primary multi-beamlet forming unit below.

In an example, an active multi-aperture element comprises an outer or peripheral zone, where the at least first and second voltage supply units are arranged, and an inner or membrane zone with the plurality of J apertures. In this example, a second shielding member can be provided between an outer or peripheral zone and the membrane zone. According to this example, the first voltage supply unit is arranged adjacent to the plurality of J apertures, and the second shielding member is arranged between the plurality of J apertures and the first voltage supply unit. Such a second shielding member can be elongated parallel to the propagation direction of the primary charged particle beamlets.

The primary multi-beamlet forming unit according to the second embodiment can further comprise a cooling member configured to reduce a thermal drift of the first voltage supply unit. A cooling member can be connected to a thermal sink outside of a vacuum chamber of the multi-beam system.

A shielding member can be provided in contact to the first voltage supply unit. In such an example, the shielding member can be identical to the cooling member. In an example, the first voltage supply unit is arranged in between the plurality of J apertures and the shielding member can be configured a cap or platelet attached to and covering the first voltage supply unit.

According to an example, the shielding member comprises a material of a first group of materials comprising Molybdenum, Ruthenium, Rhodium, Palladium or Silver. Such a shielding member can be configured with a thickness D exceeding 1 mm. Thereby, more than 80% of the secondary radiation can be absorbed.

According to an example, the shielding member comprises a material of a second group of materials comprising Tungsten, Rhenium, Osmium, Iridium, Platinum, Gold or Lead. Such a shielding member can be provided with a smaller thickness, for example of about 100 μm or more. Thereby, more than 80% of the secondary radiation can be absorbed. In both examples, the shielding member can be connected to ground level, such that any charging of the shielding layer is prevented.

In a third embodiment of the disclosure, a method of extending a lifetime of an active multi-aperture element is provided. According to the third embodiment, such a method of operating a multi-beam array element comprises the steps of:
a) performing a series of inspection tasks and monitoring a voltage drift of an active multi-aperture element or an imaging performance; and
b) triggering an annealing step of the active multi-aperture element if a voltage drift or an image performance exceeds a predetermined threshold.

The annealing step comprises at least one of a treatment of a voltage supply unit of the active multi-aperture element with pulse of a voltage VG, or a thermal annealing with a temperature of above 200°° C., for example above 250°

The annealing step can further comprise at least one of a treatment of a membrane zone of the active multi-aperture element with pulse of a voltage VG, a thermal annealing with a temperature above 250° C., or a low energy plasma treatment.

Local charging effects can be induced in the membrane zone or in the voltage supply unit by secondary radiation. With the pulse of a voltage VG, local charging effects can be reduced. Local damages can be generated by x-ray radiation, for example at interfaces of silicon and silicon oxide layers or structures within the membrane zone or the voltage supply units. With thermal or plasma annealing step, at least some of the local damages can be repaired. However, even with repeated annealing steps, damages will accumulate. The method can thus further monitor a dose of secondary radiation, a number or frequency of annealing steps, and predicting a lifetime end of the voltage supply unit or the active multi-aperture element.

In a fourth embodiment, a method of operation of an active multi-aperture element is provided. The method of operating an active multi-aperture element of a multi-beam charged particle microscope comprises the steps of:
a) determining, in a calibration step, a plurality of digital control signals for the control of at least a first and a second voltage supply unit. The first and second voltage supply unit are configured for providing a plurality of voltages to at least a first and a second group of electrodes of a plurality of electrodes of the active multi-aperture element. In an example, the of a plurality of electrodes form a plurality of multi-pole elements.
b) performing a sequence of inspection tasks;
c) monitoring an imaging performance with an image quality monitor of the multi-beam charged particle microscope or a voltage drift of at least the first voltage supply unit;
d) triggering a voltage correction step, if the imaging performance or the voltage drift exceeds a predetermined threshold;
e) determining, during the voltage correction step, a set of compensating digital control signals for controlling at least the second voltage supply unit; and
f) providing the compensating digital control signals at least to the second voltage supply unit.
   With the method, a drift in a first voltage supply unit is compensated by providing corrected signals to a second voltage supply unit. An effect of drift of a first voltage
supply unit is thus compensated by providing corrected voltages by a second voltage supply unit. According to the fourth embodiment, the set of compensating digital control signals is determined according to the voltage drift of the at least first voltage supply unit.

According to the disclosure, a drift of a voltage supply unit can be effectively reduced by a shielding member or by a cooling member. Thereby, and damage of multi-aperture elements and the voltage supply units by x-ray radiation is minimized. A multi-beam system can further be provided with of a voltage monitor. With the method of operation and the multi-beam system being configured for executing the method, effects of voltage drifts of voltage supply units can be reduced. This allows for a longer use of active multi-aperture plates.

With the annealing methods described above, local charging and local defects can at least partially be reduced or cured and a lifetime of a multi-aperture element or a voltage supply unit can be extended. The up-time of a multi-beam charged particle microscope is thus increased and service or maintenance including the replacement of expensive parts is reduced.

The disclosure provides an array of electrostatic elements such as electrostatic micro-lenses or electrostatic multi-pole elements are described, to which driving voltages are provided by at least one voltage supply unit. However, active multi-aperture elements can also be configured as magneto-dynamic elements with coils instead of electrodes. In these equivalent examples, driving currents are provided by at least one current supply unit, which can for example be comprising an ASIC or other equivalent micro-electronic devices. Therefore, coils, driving currents or current supply units are equivalent mechanisms for electrodes, driving voltages or voltage supply units and the disclosure can be applied to magneto-dynamic array elements without difficulty.

It will be understood that the disclosure is not limited to the embodiments and examples, but comprises also combinations and variations of the embodiments and examples.

### BRIEF DESCRIPTION OF THE DRAWINGS

Embodiments of the present disclosure will be explained in more detail with reference to drawings, in which:

FIG. 1 is a schematic sectional view of a multi-beam charged particle system for wafer inspection according to the first embodiment;

FIGS. 2A-2B illustrate a multi-beam forming unit;

FIG. 3 illustrates a top view of a multi-pole array element;

FIG. 4 illustrates a segment of the multi-pole array element of FIG. 3;

FIG. 5 illustrates a segment of an alternative multi-pole array element;

FIG. 6 illustrates a top view of a further example of a multi-pole array element;

FIG. 7 illustrates a multi-beam forming unit with shielding members;

FIGS. 8A-8B illustrate a further example of a multi-pole array element;

FIG. 9 illustrates a method of operating a multi-pole array element with extended lifetime;

FIG. 10 illustration of a spot aberration induced by a global voltage offset of an individual voltage supply unit;

FIG. 11 illustrates a method of operating a multi-pole array element with reduced impact of a voltage drift;

FIG. 12 illustration of a multi-aperture element formed as a micro-lens array comprising a plurality of ring electrodes;

FIG. 13 illustrating a vacuum compartment with a thermal or plasma annealing of the primary multi-beamlet forming unit; and

FIG. 14 illustrates a further example of a multi-beam forming unit with shielding members.

### DESCRIPTION OF EXEMPLARY EMBODIMENTS

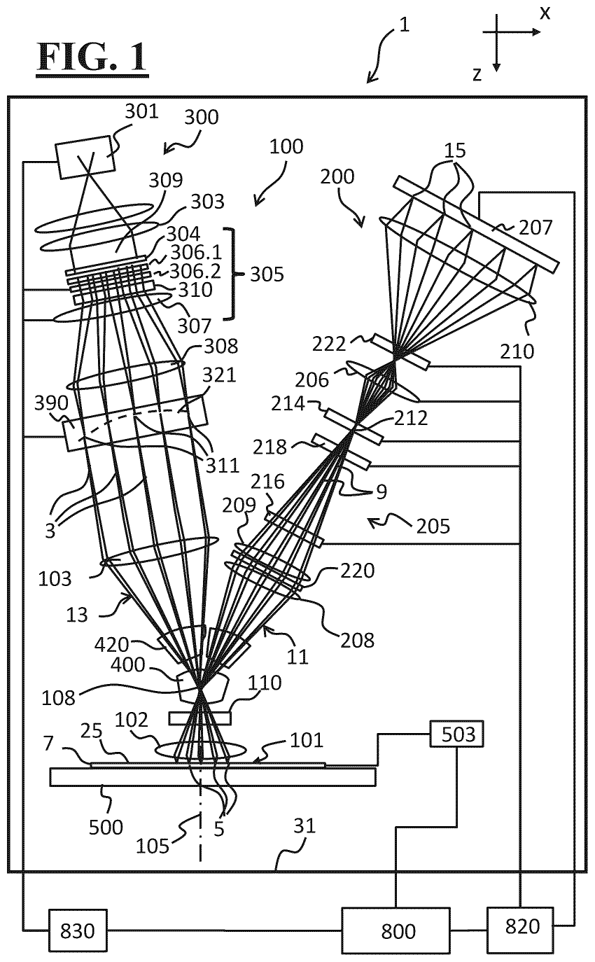

In the exemplary embodiments of the disclosure described below, components similar in function and structure are indicated as far as possible by similar or identical reference numerals. The multi-beam raster units of the examples are described in the illumination beam path with charged particles propagating in positive z-direction with the z-direction pointing downwards. However, multi-beam raster units can also be applied in the imaging beam path, with secondary charged particle beamlets propagating in negative z-direction in the coordinate system of FIG. 1. Still, the sequence of multi-aperture elements is arranged in sequence in the propagating direction of the transmitting charged particle beam or beamlets. With beam entrance side or upper side is understood the first surface or side of an element in the direction of the transmitting charged particle beam or beamlets, with bottom side or beam exiting side is understood the last surface or side of an element in the direction of the transmitting charged particle beam or beamlets.

The schematic representation of FIG. 1 illustrates basic features and functions of a multi-beam charged-particle microscopy system 1 according to the embodiments of the disclosure. It is to be noted that the symbols used in the figure have been chosen to symbolize their respective functionality. The type of system shown is that of a multi-beam scanning electron microscope (MSEM or Multi-SEM) using a plurality of primary electron beamlets 3 for generating a plurality of primary charged particle beam spots 5 on a surface 25 of an object 7, such as a wafer located with a top surface 25 in an object plane 101 of an objective lens 102. For simplicity, only five primary charged particle beamlets 3 and five primary charged particle beam spots 5 are shown. The features and functions of multi-beamlet charged-particle microscopy system 1 can be implemented using electrons or other types of primary charged particles such as ions and in particular Helium ions. Further details of the microscopy system 1 are provided in German Patent application 102020209833.6, filed on Aug. 5, 2020, which is hereby fully incorporated by reference.

The microscopy system 1 comprises an object irradiation unit 100 and a detection unit 200 and a beam splitter unit 400 for separating the secondary charged-particle beam path 11 from the primary charged-particle beam path 13. Object irradiation unit 100 comprises a charged-particle multi-beam generator 300 for generating the plurality of primary charged-particle beamlets 3 and is adapted to focus the plurality of primary charged-particle beamlets 3 in the object plane 101, in which the surface 25 of a wafer 7 is positioned by a sample stage 500.

The primary beam generator 300 produces a plurality of primary charged particle beamlet spots 311 in an intermediate image surface 321, which is typically a spherically curved surface. The positions of the plurality of focus points (311) of the plurality of primary charged particle beamlets (3) is generated and adjusted in the intermediate image surface (321) by the multi-beam generating unit (305) to pre-compensate field curvature and image plane tilt of the elements of the object irradiation unit (100) downstream of the multi-beam generating unit 305.

The primary beamlet generator 300 comprises a source 301 of primary charged particles, for example electrons. The primary charged particle source 301 emits a diverging primary charged particle beam, which is collimated by at least one collimating lens 303 to form a collimated or parallel primary charged particle beam 309. The collimating lens 303 is usually consisting of one or more electrostatic or magnetic lenses, or by a combination of electrostatic and magnetic lenses. The collimated primary charged particle beam is incident on the primary multi-beam forming unit 305. The multi-beam forming unit 305 basically comprises a first multi-aperture element or filter plate 304 illuminated by the collimated primary charged particle beam 309. The first multi-aperture element or filter plate 304 comprises a plurality of apertures in a raster configuration for generation of the plurality of primary charged particle beamlets 3, which are generated by transmission of the collimated primary charged particle beam 309 through the plurality of apertures. The multi-beamlet forming unit 305 of this example comprises two active multi-aperture elements 306.1-306.2, which are located, with respect to the direction of movement of the electrons in beam 309, downstream of the first multi-aperture or filter plate 304. For example, a first active multi-aperture element 306.1 has the function of a micro lens array, comprising a plurality of ring electrodes, each ring electrode set to a defined potential so that the focus positions of the plurality of primary beamlets 3 are adjusted in the intermediate image surface 321. A second active multi-aperture element 306.2 is configured as a deflector of multi-pole array and comprises for example two, four or eight electrostatic elements for each of the plurality of apertures, for example to deflect each of the plurality of beamlets individually. The multi-beamlet forming unit 305 according to some embodiments is configured with a terminating multi-aperture element (310). The multi-beamlet forming unit 305 is further configured with an adjacent electrostatic field lenses 307, which is in some examples combined with the multi-beamlet forming unit 305. Together with an optional second field lens 308, the plurality of primary charged particle beamlets 3 is focused in or in proximity of the intermediate image surface 321.

In or in proximity of the intermediate image surface 321, a further active multi-aperture element configured as a beam steering multi aperture element 390 can be arranged with a plurality of apertures with electrostatic elements, for example deflectors, to manipulate individually the propagation direction of each of the plurality of charged particle beamlets 3. The apertures of the beam steering multi aperture element 390 are configured with larger diameter to allow the passage of the plurality of primary charged particle beamlets 3 even in case the focus spots 311 of the primary charged particle beamlets 3 are located on the curved intermediate image surface 321. The primary charged-particle source 301, each of the active multi-aperture elements 306 and the beam steering multi aperture element 390 are controlled by primary beamlet control module 830, which is connected to control unit 800.

The plurality of focus points of primary charged particle beamlets 3 passing the intermediate image surface 321 is imaged by field lens group 103 and objective lens 102 into the image plane 101, in which the surface 25 of the wafer 7 is positioned. A decelerating electrostatic field is generated between the objective lens 102 and the wafer surface by application of a voltage to the wafer by the sample voltage supply (503). The object irradiation system 100 further comprises a collective multi-beam raster scanner 110 in proximity of a first beam cross over 108 by which the plurality of charged particle beamlets 3 can be deflected in a direction perpendicular to the propagation direction of the charged particle beamlets. The propagation direction of the primary beamlets throughout the examples is in positive z-direction. Objective lens 102 and collective multi-beam raster scanner 110 are centered at an optical axis 105 of the multi-beam charged-particle system 1, which is perpendicular to wafer surface 25. The plurality of primary charged particle beamlets 3, forming the plurality of beam spots 5 arranged in a raster configuration, is scanned synchronously over the wafer surface 25. In an example, the raster configuration of the focus spots 5 of the plurality of N primary charged particle 3 is a hexagonal raster of about one hundred or more primary charged particle beamlets 3, for example N=91, N=100, or N approximately 300 beamlets. The primary beam spots 5 have a distance about 6 μm to 15 μm and a diameter of below 5 nm, for example 3 nm, 2 nm or even below. In an example, the beam spot size is about 1.5 nm, and the distance between two adjacent beam spots is 8 μm. At each scan position of each of the plurality of primary beam spots 5, a plurality of secondary electrons is generated, respectively, forming the plurality of secondary electron beamlets 9 in the same raster configuration as the primary beam spots 5. The intensity of secondary charged particle beamlets 9 generated at each beam spot 5 depends on the intensity of the impinging primary charged particle beamlet 3, illuminating the corresponding spot 5, the material composition and topography of the object 7 under the beam spot 5, and the charging condition of the sample at the beam spot 5. Secondary charged particle beamlets 9 are accelerated by an electrostatic field generated by a sample charging unit 503 between the sample 7 and the objective lens 102. The plurality of secondary charged particle beamlets 9 are accelerated by the electrostatic field between objective lens 102 and wafer surface 25 and are collected by objective lens 102 and pass the first collective multi-beam raster scanner 110 in opposite direction to the primary beamlets 3. The plurality of secondary beamlets 9 is scanning deflected by the first collective multi-beam raster scanner 110. The plurality of secondary charged particle beamlets 9 is then guided by beam splitter unit 400 to follow the secondary beam path 11 of the detection unit 200. The plurality of secondary electron beamlets 9 is travelling in opposite direction from the primary charged particle beamlets 3, and the beam splitter unit 400 is configured to separate the secondary beam path 11 from the primary beam path 13 usually via magnetic fields or a combination of magnetic and electrostatic fields. Optionally, additional magnetic correction elements 420 are present in the primary as well as in the secondary beam paths.

The microscopy system 1 comprises a vacuum chamber 31 for maintaining a vacuum environment for the charged particle beams. The vacuum chamber 31 is illustrated very schematically. Parts of the vacuum chamber 31 can be formed by a beam tube around the plurality of primary or secondary charged particle beamlets. Other functional elements of the charged particle optical system can be arranged outside the vacuum chamber 31.

Detection unit 200 images the secondary electron beamlets 9 onto the image sensor 207 to form there a plurality of secondary charged particle image spots 15. The detector or image sensor 207 comprises a plurality of detector pixels or individual detectors. For each of the plurality of secondary charged particle beam spots 15, the intensity is detected separately, and the material composition of the wafer surface 25 is detected with high resolution for a large image patch of the wafer with high throughput. For example, with a raster of 10×10 beamlets with 8 μm pitch, an image patch of approximately 88 μm×88 μm is generated with one image scan with collective multi-beam raster scanner 110, with an image resolution of for example 2 nm or below. The image patch is sampled with half of the beam spot size, thus with a pixel number of 8000 pixels per image line for each beamlet, such that the image patch generated by 100 beamlets comprises 6.4 gigapixel. The digital image data is collected by control unit 800. Details of the digital image data collection and processing, using for example parallel processing, are described in German patent application 102019000470.1 and in US-patent U.S. Pat. No. 9,536,702, which are hereby incorporated by reference.

Projection system 205 further comprises at least a second collective raster scanner 222, which is connected to scanning and imaging control unit 820. Control units 800 and imaging control unit 820 are configured to compensate a residual difference in position of the plurality of focus points 15 of the plurality of secondary electron beamlets 9, such that the positions of the plurality secondary electron focus spots 15 are kept constant at image sensor 207.

The projection system 205 of detection unit 200 comprises further electrostatic or magnetic lenses 208, 209, 210 and a second cross over 212 of the plurality of secondary electron beamlets 9, in which an aperture 214 is located. In an example, the aperture 214 further comprises a detector (not shown), which is connected to imaging control unit 820. Imaging control unit 820 is further connected to at least one electrostatic lens 206 and a third deflection unit 218. The projection system 205 can further comprise at least a first multi-aperture corrector 220, with apertures and electrodes for individual influencing each of the plurality of secondary electron beamlets 9, and an optional further active element 216, connected to control unit 800 or imaging control unit 820.

The image sensor 207 is configured by an array of sensing areas in a pattern compatible to the raster arrangement of the secondary electron beamlets 9 focused by the projecting lens 205 onto the image sensor 207. This enables a detection of each individual secondary electron beamlet independent from the other secondary electron beamlets incident on the image sensor 207. The image sensor can also serve as an image quality monitor of the multi-beam charged particle microscope 1. The image sensor 207 illustrated in FIG. 1 can be an electron sensitive detector array such as a CMOS or a CCD sensor. Such an electron sensitive detector array can comprise an electron to photon conversion unit, such as a scintillator element or an array of scintillator elements. In another embodiment, the image sensor 207 can be configured as electron to photon conversion unit or scintillator plate arranged in the focal plane of the plurality of secondary electron particle image spots 15. In this embodiment, the image sensor 207 can further comprise a relay optical system for imaging and guiding the photons generated by the electron to photon conversion unit at the secondary charged particle image spots 15 on dedicated photon detection elements, such as a plurality of photomultipliers or avalanche photodiodes (not shown). Such an image sensor is disclosed in U.S. Pat. No. 9,536,702, which is cited above and incorporated by reference. In an example, the relay optical system further comprises a beam splitter for splitting and guiding the light to a first, slow light detector and a second, fast light detector. The second, fast light detector is configured for example by an array of photodiodes, such as avalanche photodiodes, which are fast enough to resolve the image signal of the plurality of secondary electron beamlets 9 according to the scanning speed of the plurality of primary charged particle beamlets 3. The first, slow light detector can be a CMOS or CCD sensor, providing a high-resolution sensor data signal, serving as an image quality monitor of the multi-beam charged particle microscope 1.

During an acquisition of an image patch by scanning the plurality of primary charged particle beamlets 3, it can be desirable for the stage 500 to not be moved, and after the acquisition of an image patch, the stage 500 is moved to the next image patch to be acquired. In an alternative implementation, the stage 500 is continuously moved in a second direction while an image is acquired by scanning of the plurality of primary charged particle beamlets 3 with the collective multi-beam raster scanner 110 in a first direction. Stage movement and stage position is monitored and controlled by sensors known in the art, such as Laser interferometers, grating interferometers, confocal micro lens arrays, or similar.

According to an embodiment of the disclosure, a plurality of electrical signals is created and converted in digital image data and processed by control unit 800. During an image scan, the control unit 800 is configured to trigger the image sensor 207 to detect in predetermined time intervals a plurality of timely resolved intensity signals from the plurality of secondary electron beamlets 9, and the digital image of an image patch is accumulated and stitched together from all scan positions of the plurality of primary charged particle beamlets 3.

A multi-beam generating unit 305 is for example explained in U.S. application Ser. No. 16/277,572, publication number US 2019/0259575, and in U.S. application Ser. No. 16/266,842, filed on Feb. 4, 2019, both hereby incorporated by reference. Further details of a multi-beam generating unit 305, which is insensitive to fabrication errors and scattering are disclosed in PCT/EP2021/025095, filed on 9 Mar. 2021, which is hereby incorporated by reference.

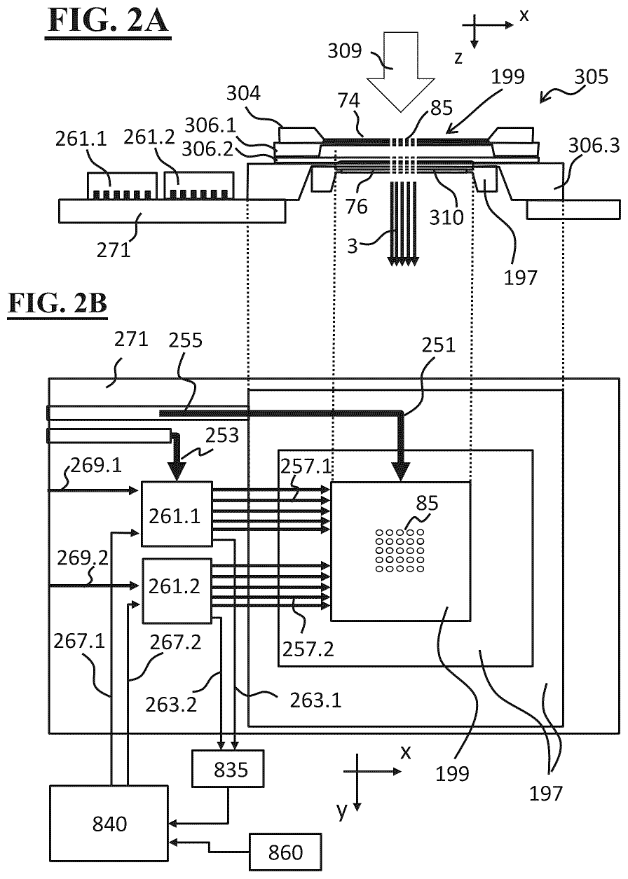

To enhance the performance of the multi-beam charged particle microscope during use, each of the plurality of charged particle beamlets is individually controlled, for example by individual focus correction with a plurality of individually controlled ring electrodes of the micro lens array 306.1, or a plurality of individually controlled electrodes of stigmators or multi-pole array element 306.2. The individual control of the voltages of the plurality of electrodes is provided by programmable control elements. A first embodiment of the disclosure of a control architecture for the generation and control of a plurality of voltages is illustrated in FIGS. 2A-2B. A primary multi-beamlet forming unit 305, comprising multi-aperture elements 304, 306 and 310, each with a parallel arranged membrane in membrane zone 199 and a support structures in a support zone 197, is mounted on a carrier or support board 271 with the additional function of a support board. In this example, the primary multi-beamlet forming unit 305 comprises three active multi-aperture elements 306, including a micro-lens array element 306.1 and a multi-pole array element 306.2, each comprising a plurality of electrodes arranged at each aperture 85. A further active multi-aperture element 306.3 can be for example a second multi-pole array element. At least two ASICS 261.1 and 261.2 are mounted on the support board 271. For example, the ASICS form the voltage supply units for the plurality of electrodes of the active multi-aperture elements. ASICS or voltage supply units may be provided for the ring electrodes of the micro-lens array 306.1 and the electrodes of the multi-pole array element 306.2. The electrodes are connected to the voltage supply units 261 by low voltage wiring connections 257.1 and 257.2. ASICS are controlled by digital signals via digital signal lines 267.1 and 267.2 and receive power from a power supply (not shown) by low voltage supply lines 269.1 and 269.2. In the example, only J=25 apertures (85) in the membrane zone 199 are shown, and only two ASICS 261.1 and 261.2. The plurality of J apertures 85 can be larger, for example J=91, J=100 or more, for example J=1000. The number of electrodes for each multi-pole element can for example be six, eight or twelve electrodes at each aperture, and the total number of electrodes can easily exceed more than 500, for example more then 700, or even more, for example for J=1000, a multi-pole array element has up to 12000 electrodes. In addition, individual voltages are provided to the plurality of J ring electrodes of active multi-aperture element 306.1 forming the micro-lens array. Therefore, also the number of ASICS can be significantly larger than two, for example 6, 8 or even about up to 100 ASICS can be used. The ASCIS form a plurality of digital to analog converters (DACs), for example for providing analogue voltages to the electrodes, with one DAC for each electrode. In an example, a multi-beam raster unit 305 for a plurality of J=91 beamlets involves at least 728 individual DACs and 728 individual wiring connections 257 to the 728 electrodes.

FIG. 2A shows a cross section through an example of a primary multi-beamlet forming unit 305 according to the first embodiment. The primary multi-beamlet forming unit 305 comprises the filter plate 304 and several active multi-aperture elements 306.1 to 306.3 with different functions. It further comprises a terminating multi aperture element 310. At the beam entrance or upper side 74, a primary electron beam 309 is incident. The plurality of primary electron beamlets 3 exits from the primary multi-beamlet forming unit 305 at the bottom side or beam exiting side 76. Each of the multi-aperture elements 304, 306 and 310 comprises an inner membrane zone 199 with the plurality of apertures 85 arranged in the raster configuration of the plurality of primary electron beamlets 3, which are generated by the primary multi-beamlet forming unit 305. Each multi-aperture element 304, 306 and 310 further comprises a support zone 197, by which the multi aperture elements are aligned with respect to each other and mounted. The primary multi-beamlet forming unit 305 further comprises a carrier element 271, to which a support zone 197 of at least one multi-aperture element is attached. On the carrier element, a plurality of voltage supply units including the ASICs 262.1 and 262.2 are arranged. With the microelectronic devices such as ASIC devices 262.1 and 262.2, the plurality of voltages used for the plurality of electrodes of the active multi-aperture array elements are generated and provided.

FIG. 2B shows a top view in positive z-direction on the primary multi-beamlet forming unit 305. Same elements are labeled by identical reference numbers. For the individual control of the plurality of electrodes, the electrodes are connected to the microelectronic devices such as ASIC device 262.1 and 262.2 by wiring connections 257. Additional wirings can be provided for shielding and absorbing layers, or for sensors. High voltages are provided by an external controller and with connections 251 to the multi-aperture elements or with connections 253 to the ASICS 261. High voltage connections 251 and 253 can be electrically shielded by coaxial shielding casings 255. The electrodes use drive voltages with differences of orders of magnitude, for example between 10V up to 1 kV. For example, a multi lens array 306.1 can use J voltage wirings for providing about 200V to each of the ring electrodes of the lens array (not shown). The multi-pole array 306.2 for beam correction and deflection involves for example J times eight voltage wirings for providing of about few volts with very low noise. The voltages are provided by ASICs 261.1 and 261.2 (only two shown), which are placed inside the vacuum with digital interface to an array control unit 840. The array control unit 840 is element of the primary beam-path control module 830, configured for the control of active multi-aperture elements 306.1 to 306.3.

The routing of signals and voltage supply is obtained via an UHV-Flange (not shown). In an example, the ASICs or voltage supply units 261.1 and 261.2 are further connected to a voltage drift monitor 835, which controls at least a representative voltage or voltage control output 263.1 and 263.2 of each of the ASICS. The voltage drift monitor 835 is connected to the array control unit 840. The array control unit 840 is configured to evaluate the voltage control outputs 263.1 and 263.2 and is configured to compensate a drift for example in a first voltage supply unit or ASIC 261.1 by computing digital control signals provided to the first or second voltage supply unit 261.1 or 261.2. The array control unit 840 is further connected to an image performance sensor 860, which provides input to the array control unit 840 for the determination of the digital control signals provided to the ASICS 261.1 and 261.2 via digital signal lines 267.1 and 267.2. For example, an astigmatism of an individual beamlet is determined and corresponding signals for the correction of the astigmatism are derived to compensate the astigmatism by the multi-pole element corresponding to the individual beamlet. With the architecture provided above, a precise and reliable control of a multi-pole array element is enabled. More details will be explained below.

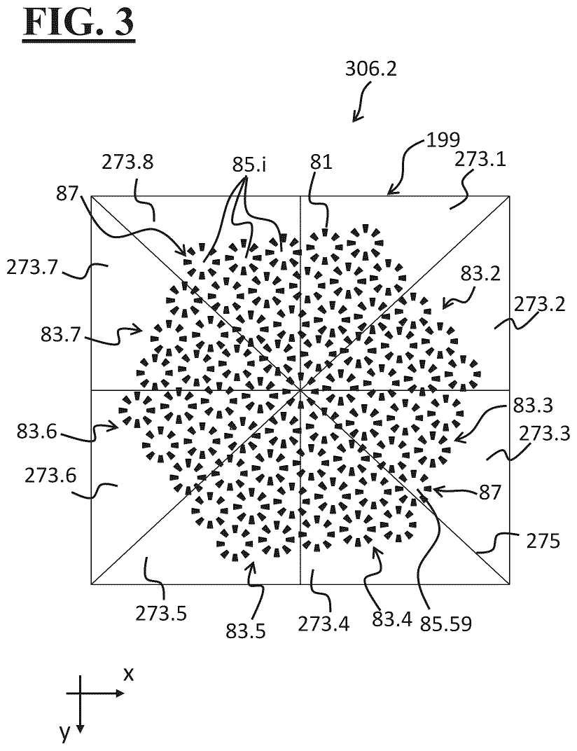

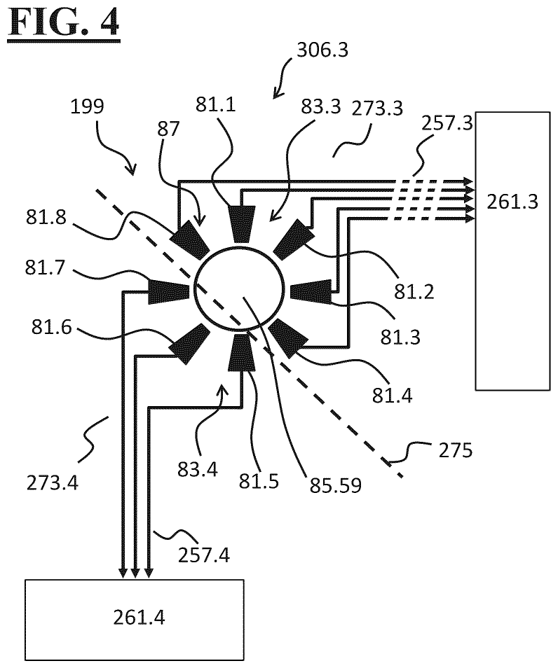

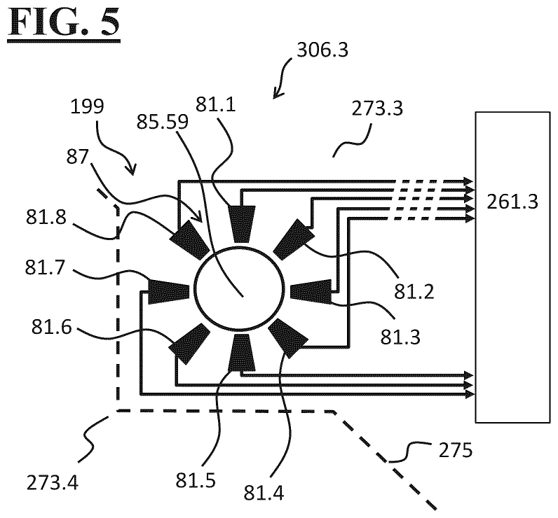

FIG. 3 shows an example of an active multi aperture element formed as a multi-pole array 306.2 with a plurality of J apertures 85 arranged in a hexagonal raster configuration. The raster configuration is rotated with respect to the x-y axes. Thereby a rotation of the magneto-dynamic objective lens 102 and other magnetic lenses is pre-compensated. At each of the plurality of apertures, eight electrodes 81 are arranged, forming a multipole element 87. In this example, only J=61 apertures with J=61 multi-pole elements 87 are illustrated. The multi-pole array 306.1 is configured in 8 segments 273.1 to 273.8 with segment borders 275. Each segment comprises a group of electrodes 83.1 to 83.8. A segment border is illustrated in FIG. 4 at the example of the multi-pole elements 87 at aperture 85.59 with the electrodes 81.1 to 81.4 and electrode 81.8 being members of a third group of electrodes 83.3 and the electrodes 81.5 to 81.2 being members of a fourth group of electrodes 83.4. For sake of simplicity, only a single aperture and a single multipole element 87 is shown. In an example, the electrodes 81 in a segment 273 form a first group of electrodes, which is connected to a first voltage supply unit 261.3. The electrodes in segment 261.4 form a second group of electrodes, which is connected to voltage supply unit 261.4. A global drift in the voltage supply unit 261.3 can therefore be compensated by applying a local compensation voltage offset to the electrodes of aperture 85.59 of the second group of electrodes of segment 273.4. Thereby, the relative voltage difference between the eight electrodes 81.1 to 81.8 is maintained and the multi-pole elements 87 perform in the expected, predetermined manner. FIG. 5 illustrate another example, where the segments are selected in a way that the electrodes of each multipole-element, in this example of multipole element 87 at aperture 85.59, are attributed and connected to only on voltage supply unit 261.3. In this example, a global drift of the voltage supply unit 261.3 has no impact on the relative voltage difference between the eight electrodes 81.1 to 81.8 and the multi-pole elements 87 perform in the expected, predetermined manner. However, a voltage supply unit 261 can also have only local voltage drifts or can be constituted by a plurality of micro-electronic subunits, such as in multi-core architecture. In other examples, the segments are not formed as angular segments.

According to the example of FIG. 5, a multi-beam array element 306.2 for a multi-beam system (1), comprises an inner membrane zone 199 with a plurality of J apertures 85 arranged in a raster configuration, configured for transmitting during use a plurality of J primary charged particle beamlets 3. The multi-beam array element 306.2 further comprises a plurality of J multi-pole elements (87), each multi-pole element (87) comprising an aperture (85) of the plurality of J apertures (85), each multi-pole element comprising a plurality of K1 electrodes (81.1 to 81.K), and each multi-pole element (87) being configured to influence one of the primary charged particle beamlets (3). The multi-beam array element 306.2 further comprises a plurality of L voltage supply units, wherein each of the K electrodes (81.1 to 81.K) of one multi-pole element (87) is connected to only one of the plurality of L voltage supply units 261. In an example, the plurality of L voltage supply units (261) is arranged on a base plate (271) in the periphery of the raster configuration of the plurality of J apertures (85).

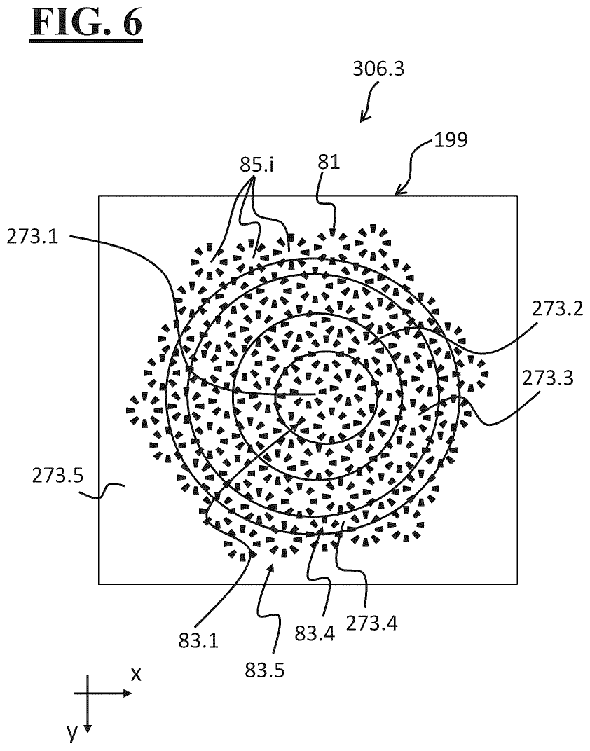

An example with annular segments 273.1 to 273.5 is illustrated in FIG. 6. A selection of annular segments is advantageous if one task of the multi-pole array element 306.2 is to contribute to a focusing power of the primary multi-beamlet forming unit 305 and to compensate a field curvature and image plane tilt of the multi-beam charged particle microscope system 1. With the assignment of multi-pole elements 87 to different ring segments, corresponding voltage supply units for the corresponding groups of electrodes are driven with similar power. A first group of electrodes of the first segment 273.1 is for example driven by larger voltages to achieve a stronger focusing power, whereas the fifth group of electrodes of the fifth segment 273.5 is driven on average with a lower voltage. The fifth group of electrodes is thus less effected by for example thermal drifts of the first voltage supply unit 261.1 for the first group of electrodes.

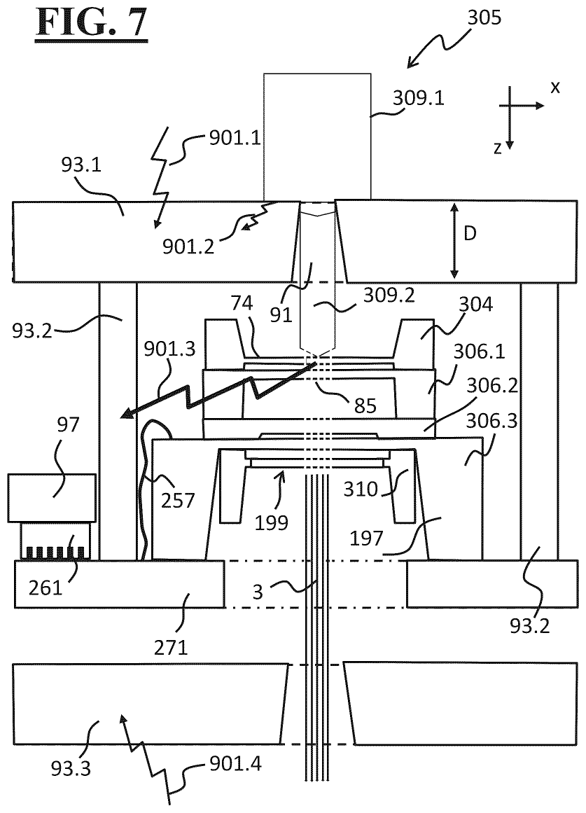

The performance of the multi-pole array element 306.2 is sensitive to drifts of the voltage supply units 261. The voltage supply units 261 can show drifts of the voltages over time or can accumulate different voltage offsets over time. Furthermore, incorrect voltages generated for the multi-pole array element 306.2 can be the result of a local or global damage of a voltage supply unit 261. Secondary radiation, as for example x-ray radiation can be one source for different offset voltages or damages. According to a second embodiment of the disclosure, the impact of secondary radiation is reduced by a shielding member. An example is illustrated in FIG. 7. In FIG. 7, a thick absorber or first shielding member 93.1 is provided at the entrance side 74 of the filter plate 304. The first shielding member 93.1 has an aperture 91, which is configured to limit the primary beam 309 to the area used to illuminate the raster of apertures 85. In an example, the aperture 91 has a conical shape with an increasing diameter in z-direction. Thereby, scattering of the primary electron beam 309 at the inner side of aperture 91 is minimized. The cross section of the aperture 91 can be configured according to the area of the raster configuration, for example with an area of hexagonal shape with a diameter of about 1 mm or more. Therefore, the first shielding member 93.1 with the large aperture 91 can be provided with a large thickness. Thereby, secondary radiation 901.1 generated upstream of the first shielding plate 93.1 can effectively prevented from reaching the voltage supply units 261 and a voltage drift or damage is reduced. Furthermore, the transmission of secondary radiation 901.2 generated at first shielding member 93.1 is reduced. The first shielding member 93.1 is configured with a highly conductive material and connected to ground level. Thereby, a charging including local surface charges of the first shielding member 93.1 are avoided.

With the aperture 91 with size and area configured according to the raster of apertures 85, the beam diameter of the primary charged particle beam 309.1 is effectively reduced to the filtered primary beam 309.2 with a diameter or area according to the raster of apertures 85. Thereby, the number of absorbed electrons or generation of secondary radiation at the filter plate 304 is reduced to a minimum. The first multi-aperture element or filter plate 304 comprises an absorption layer made of a material of high density and high conductivity. The absorption layer is connected to ground level. Most primary charged particles of filtered beam 309.2 are absorbed, and the corresponding charge is dissipated to the ground level. However, still some primary electrons are scattered at the filter plate 304 and still some secondary radiation 901.3 can be generated at the filter plate 304. The secondary radiation 901.3, such as x-rays or secondary electrons, can be emitted in any direction. Especially X-rays can penetrate the thin membrane zones 199 and the support elements 197 of the active multi aperture elements 306, and can impact on the voltage supply units 261 and cause damage or charge drifts. In an example, a further damage or drift of the voltage supply units 261 is avoided. In this example, the primary multi-beamlet forming unit 305 is provided with second shielding member 93.2, which is arranged in between the multi-aperture elements 304, 306 and 310 and the voltage supply elements 261. Thereby, secondary radiation 901.3 generated in the multi-aperture elements 304, 306 and 310 is prevented from reaching the voltage supply units 261 and a drift of voltages or damage of the voltage supply units 261 is reduced. In an example, the shielding member 93.2 is arranged in the circumference of the multi-aperture elements 304, 306 and 310 and encloses the multi-aperture elements 304, 306 and 310.

The primary multi-beamlet forming unit 305 can be configured with at least the first shielding member 93.1 or the second shielding member 93.2 or a combination of both. In a further example illustrated in FIG. 7, an even further damage or drift of the voltage supply units 261 is avoided. In this example, the primary multi-beamlet forming unit 305 is provided with third shielding member 93.3, which is arranged below the multi-aperture elements 304, 306 and 310 and the voltage supply elements 261. Thereby, secondary radiation 901.4 generated by any electron-optical elements downstream of the primary multi-beamlet forming unit 305 is prevented from reaching the voltage supply units 261 and a drift of voltages or damage of the voltage supply units 261 is further reduced. In FIG. 7, only one voltage supply unit 261 is illustrated, but as explained above, several voltage supply units 261.1 to 261.N can be arranged in the circumference of the active multi-aperture array elements 306.1 to 306.3.

Secondary radiation in the form of X-ray radiation 901 can generate space charges or local charging effects in semiconductors. Charging effects can accumulate over time and can have an impact on the performance of micro-electronic devices such as transistors or capacities of a DAC. Charging effects are therefore a source of voltage drifts. X-ray radiation 901 can further be absorbed and heat is generated. A change of the operating temperature of a voltage supply unit 261 is a further source of voltage drifts. However, even with shielding members 93, the operating temperature of a voltage supply unit 261 is generally subject to its operating conditions, for example the currents used to charge the electrodes to reach the desired voltages. Since the voltage supply units 261 are arranged inside the vacuum chamber, a cooling via convective flow of heat is not possible. In an example, the voltage supply unit 261 in FIG. 7 is therefore physically connected to a cooling member 97. The cooling member 97 can be in connection to a heat sink outside the vacuum chamber 31 (see FIG. 1, not shown in FIG. 7). Thereby, the temperature of the voltage supply unit 261 can be controlled and a voltage drift by temperature can be minimized. In an example, the cooling member 97 and a shielding member 93 are identical and formed as a single member.

The effect of a shielding element 93 is typically described by an absorption coefficient μ for the secondary radiation in question. Attenuation is typically described by Lambert-Beers law with

I=I₀ exp (−μD)

with the thickness D. Measured values for absorption coefficients μ for an X-ray energy spectrum generated by 30 keV electron irradiation are for example 1.1/mm for Aluminum, 14.2/mm for Iron, and 17.5/mm for Copper. However, the x-ray spectrum generated is depending on the electron energy and the material composition of for example the filter plate 304. Generally, it is advantageous to utilize paramagnetic or diamagnetic materials of high density, for example materials of a first group of Molybdenum, Ruthenium, Rhodium, Palladium or Silver (element numbers 42, 44 to 47), or a material of a second group of materials such as Tungsten, Rhenium, Osmium, Iridium, Platinum, Gold or Lead (element numbers 74 to 79 and 82). On the other hand, other materials as for example silicon or aluminum are unsuitable for blocking x-ray radiation. Typically, the multi-aperture elements are formed by micro-structuring of silicon or silicon compounds. With the typical thickness of the multi-aperture elements 304, 306 and 310 of below 200 μm, only less than 10% of the secondary radiation is absorbed within each multi-aperture element. Even with a thick coating of for example 5 μm thickness with gold, still more than 70% of the secondary radiation is transmitted. Therefore, even thick coatings or films are not sufficient for effectively shielding the secondary radiation. Such thick coatings will also cause a stress bending or deformation of the membrane zones and are thus not possible.

According to the second embodiment, the attenuation of secondary irradiation and the prevention of charging effects or damaging of the voltage supply units is therefore achieved by the shielding members 93.1 to 93.3. The first shielding member 93.1 with a large aperture 91 with diameter of for example about 1.1 mm and area according to the raster of primary beamlets 3 can be made with sufficient thickness and of materials of sufficient absorption power and high conductivity. For example, with a shielding member with a thickness of about D=1 mm made of one of the materials of the first or second group of materials, a sufficient attenuation of secondary radiation to ratios of 10 E−5 or less is achieved. The second shielding member 93.2 is arranged between the multi-aperture elements (304, 306, 310) and the voltage supply units 261. With the second shielding member 93.2 with a thickness of about D=1 mm made of one of the materials of the first or second group of materials, a sufficient attenuation of secondary radiation to ratios of 10 E−5 or less is achieved.

A shielding member 93 can also be provided by a thick support layer of for example 2 mm thickness, made of for example aluminum or silicon and be provided with a layer of high absorbing material, for example with a layer of the second group of materials with a thickness of about 200 μm or with a layer of the first group of materials with a thickness of about 300 μm. Of course, also other materials with larger thickness, for example Copper or Zirconium are possible, or any combinations thereof. To increase the conductivity and reduce surface charges, a shielding member 93 can also be provided with a conductive surface coating, for example by a layer made from copper, gold or lead.

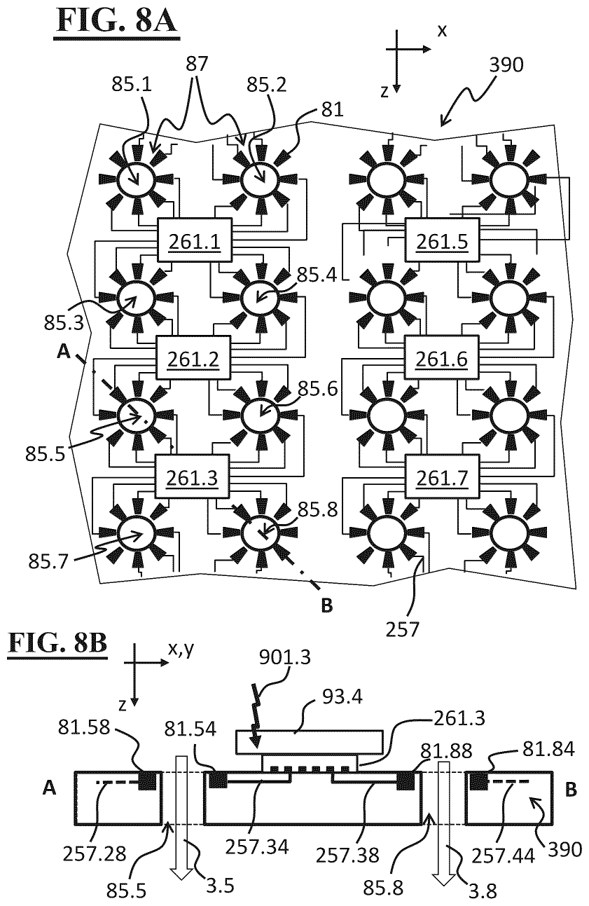

FIGS. 8A-8B show a further example of a shielding member 93.4. In some applications, the spacing between individual apertures 85 or a multi-aperture element is large enough to allow a placement or direct structuring of micro-electronic devices as voltage supply units 261 directly in between the apertures. An example is given in FIG. 1 by the multi-pole array element 390, which is configured as beam steering multi aperture element. With such an element, a telecentricity property of the plurality of primary charged particle beamlets can be corrected. In such an example, a shielding member 93.4 made of a material of the second group of materials allow a placement of the shielding member 93.4 as a covering plate of cap directly above each voltage supply unit. With a material of the second group and a thickness of the shielding member 93.4 of about 100 μm or more, a suppression of more than 99% is achieved. FIG. 8A shows an x-y cross section of a multi-pole array 390 with a plurality of apertures including apertures labelled with 85.1 to 85.8. In between the apertures 85.i, a plurality of small voltage supply units 261.1 to 261.7 formed as micro-electronic devices are placed, which serve as DAC to provide corresponding voltages to the electrodes 81 of the multi-pole elements 87. A plurality of wiring connections 257 between the voltage supply units 261.i and the electrodes 81 are shown. Further present signal lines 267 and voltage lines 269 of FIGS. 2A-2B are not shown. FIG. 8B shows a cross section along line AB, with two apertures 85.5 and 85.8. The electrodes of third group 81.54 and 81.88 are connected to voltage supply unit 261.3 by connections 257.34 and 257.38. The electrode 81.58 is an electrode of the second group, connected via line 257.28 to voltage supply unit 261.2. The voltage supply unit 261.3 is covered by the shielding member 93.4, which is formed as a cap or plate made of a material of the second group, for example Tungsten, Platinum or Lead with a thickness of about 100 μm or more. The shielding member 93.4 is configured to cover the voltage supply unit 261.3 from the entrance side of the primary charged particle beamlets 3.5 and 3.8. Thereby, secondary radiation 901.3 from the filter plate 304 above (see FIG. 7) is absorbed to more than 99% and a damage of charging of the voltage supply unit 261.3 is minimized. Of course, a further shielding member can be placed at the back side to avoid damage from secondary radiation 901.4 generated downstream of the multi-pole array 390.

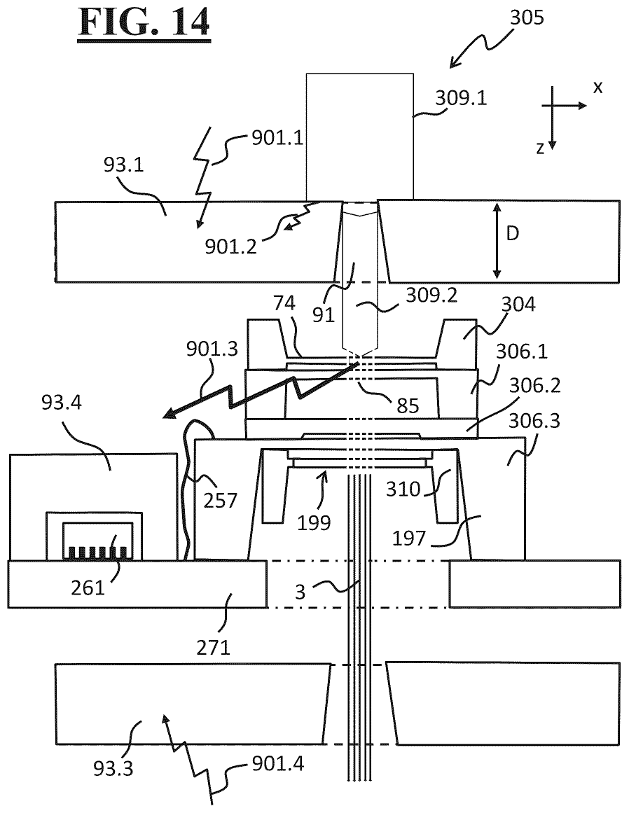

FIG. 14 illustrates a further example of a shielding member 93.4. FIG. 14 is similar to FIG. 7 and reference is made to FIG. 7 for the description. As for the example of FIG. 7, the voltage supply units 261 are arranged in the circumference of the multi-aperture elements 304, 306 and 310. In the example of FIG. 14, the shielding member 93.4 is provided to cover the voltage supply units 261 as a covering plate or cap directly above each voltage supply unit 261. Each cap may cover one or more voltage supply units 261, and each cap may have an extension in z-direction to provide a shield between the primary charged particle beamlets 3 and to mount the caps to the carrier or support board 271. Thereby, a direct contact between a voltage supply unit 261 and the shielding member 93.4 can be avoided.

Throughout the examples, the board 271 is shown as one single support board for supporting the voltage supply units 261 as well as at least one multi-aperture plate 306. It is off course also possible that for example, a multi-aperture plate 306 is mounted of a first support board 271 and the voltage supply units 261 are mounted on a second support board, mechanically separated from the first support board 271 and electrically connected to the first support board with a flexible connection similar to wiring connections 257.

With the examples of the second embodiment, a damage or charge accumulation of microelectronic circuits of the voltage supply units induced by secondary radiation is reduced to a minimum. Thereby, a significant contribution to voltage drifts is reduced.

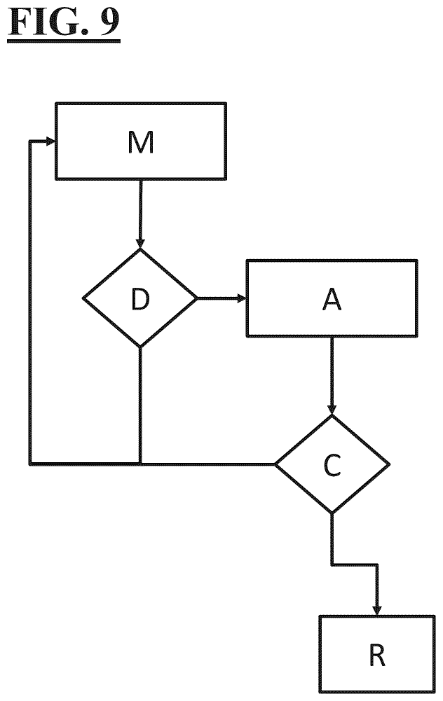

According to a third embodiment of the disclosure, a further reduction of voltage drifts induced by charge accumulation is provided. The function of micro-electronic semiconductor structures in presence of secondary radiation such as secondary electron radiation and x-rays is subject to charging effects, including for example the building of a positive space charge in silicon-oxides or surface charging effects at interfaces. Some of the charging effects can be reduced or balanced by application of pulses of a negative voltage-VG. Therefore, according to a first example of the third embodiment, a method is provided, by which charging effects of a voltage supply unit are balanced or restored by application of pulses of a negative voltage-VG to the voltage supply unit. Some charging effects and damages are however not reversible by the application of voltage pulses. Some of these charging effects or damages are however reversible by heating the microelectronic devices to temperatures above 250° C. With such a heating for several minutes, many charging effects or local damages of a voltage supply unit can be reduced or completely annealed. According to a second example of the third embodiment, the multi-aperture elements 304, 306,310 or 390 or the voltage supply units 261 are treated by voltage pulses and a thermal annealing process to reduce charging effects or damages. The thermal annealing can be achieved by external heating by resistance heaters or for example by IR laser irradiation. FIG. 9 illustrates the method. In a first step M, a series of inspection tasks is performed by the multi-beam charged particle microscope 1 according to the first embodiment. In a step D, the control unit interrupts the measurement and optionally starts the step A of an annealing procedure. After finishing the annealing procedure, the control unit triggers the continuation of the measurements with the next inspection task. The interruption of the inspection tasks in step D can be triggered by different parameters. According to a first example, an imaging performance indicator of the multi-beam charged particle microscope 1 is monitored. If a deviation of a beam quality according to a malfunction of an active multi-aperture element 306 is detected, a trigger signal is generated to start an annealing process A. According to a second example, a representative voltage output is measured by voltage drift monitor 835 (see FIGS. 2A-2B). If a voltage drift exceeds a predetermined threshold, a trigger signal is generated to start an annealing process A. According to a third example, the trigger signal is generated by model-based control. An estimated voltage drift over time or accumulated exposure dose is computed, and the trigger signal is generated when the estimated voltage drift over time or accumulated exposure dose exceeds a predetermined threshold. The annealing procedure according to step A can comprise a negative voltage pulse or a thermal annealing applied to the voltage supply units 261, or a combination of both.

With the method according to the third embodiment, a lifetime of a voltage supply unit can be extended. In optional step C, a success of the annealing process is determined. With increasing age or exposure dose of a voltage supply unit, irreversible damages will accumulate and slowly diminish the performance of a voltage supply unit over time. After reaching a certain damage level even after repeated annealing, a replacement step R can be triggered for replacement of a multi-beam forming unit 305 or an active multi-aperture element 390.

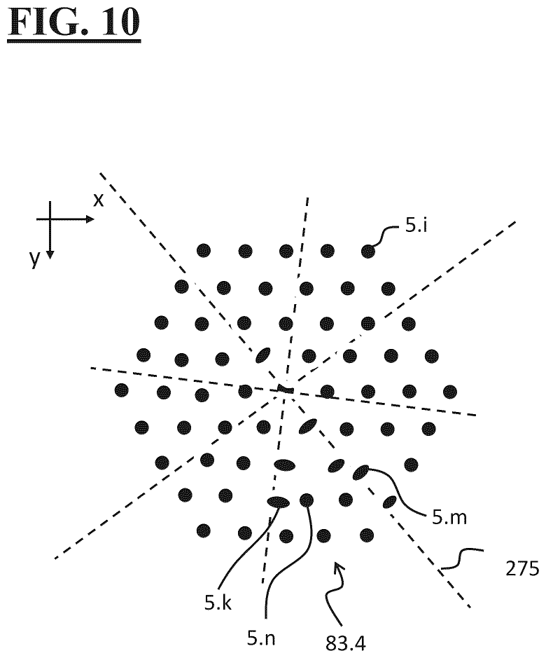

A multi-pole array according to the embodiments can comprise more than 488 electrodes (see FIG. 3). With an increasing number J of beamlets, and a better accuracy of the correction of each individual beamlet by for example a multi-pole element 87 with twelve electrodes, the number of electrodes to be supplied with individual voltages can increase to numbers well beyond 1000 for a single multi-pole array 306.2. In advanced multi-beam charged particle microscopes, more than on multi-pole array can be involved. In an example, two multi-pole arrays are used to achieve a deflection and angle correction of the plurality of primary beamlets. In a further example, four or five multi-pole arrays are used to achieve an individual focusing power for each beamlet. Therefore, a very large number of individual voltages are to be generated, controlled, and provided for the plurality of electrodes. According to a fourth embodiment, a method is provided to operate the plurality of electrodes of an active multi aperture element such as a multi-pole array or a micro-lens array by at least two voltage supply units. In an example, an array of octupoles is controlled using multiple Voltage supply units, for example ASICS forming an array of DACs with for example 128 DAC channels each. Due to routing restrictions, some octupoles are controlled by more than one ASIC (see FIGS. 3 and 4). In such examples, a voltage offset, or voltage drift of a first ASIC has an effect on the beam quality or beam deflection. An example is illustrated in FIG. 10. FIG. 10 illustrates an effect of a global voltage offset of one voltage supplier, as it can be measured with an image quality monitor of a multi-beam charged particle system 1. In the example, the voltage supply unit 261.4 for the electrodes in section 83.4 has an offset. A beam spot 5.n with all electrodes of the corresponding multi-pole element supplied by the same voltage supply unit 261.4 does not show any deviations, because all electrodes are just provided with a constant global voltage offset. However, a focus spot 5.k or 5.m with a corresponding multi-pole element with voltages supplied by at least two different voltage supply units show an astigmatic behavior and/or a deflection due to the asymmetry by the voltage offset. From the positions and the effect of the deflection or beam shape of a spot 5.1 . . . J, an offset voltage of a voltage supply unit 261 can be determined. The primary electron spots 5.1 . . . J can either be measured directly in a mirror imaging method, or the beam aberrations can be determined from an image acquisition of a calibration test sample.

According to the example of FIG. 4, a first group of electrodes 81.1 to 81.4 and 81.8 is controlled by a first voltage supply unit 261.3, and a second group of electrodes 81.5 to 81.7 is controlled by a second voltage supply unit 261.4. A voltage offset of the first voltage supply unit 261.3 introduces in this example a beam tilt. The beam tilt can be compensated by an equivalent voltage offset of the electrodes 81.5 to 81.7 of the second group of electrodes. The method is not limited to only two voltage supply units and two corresponding groups of apertures. A multi-beam forming unit can involve 6, 8, 10, or even more voltage supply units. An example is also shown in FIGS. 8A-8B, where smaller voltage supply units with less DAC channels are used. Here, for example, with an array of 10×10 apertures, fifty voltage supply units with fifty groups of electrodes are utilized.

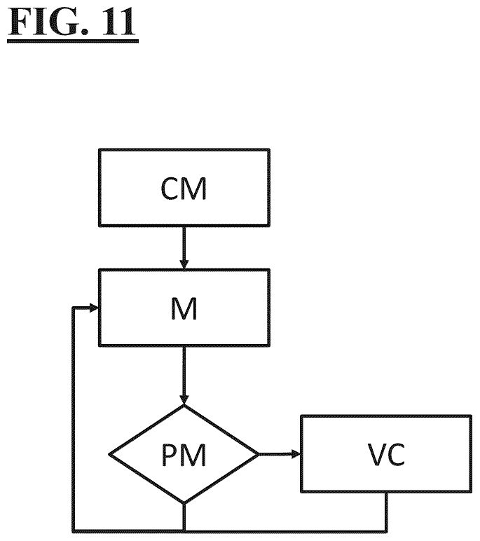

The method according to the fourth embodiment is described in FIG. 11 in more detail. In a first step CM, the digital control signals for the control of the voltage supply units are determined. The determination can for example be performed during a calibration step of the multi-beam charged particle microscope 1, wherein an imaging performance is optimized by optimized control parameters of the multi-beam charged particle microscope 1, including the optimized digital control signals for the control of the voltage supply units for the operation of the active multi-aperture elements 306, including the multi-pole arrays 306.2 or 390. During the performance of a sequence of inspection tasks in step M, the performance is repeatedly monitored in step PM. If a performance parameter exceeds a predetermined threshold, a voltage correction step VC is triggered. In a first example, the monitoring step is performed by an image quality monitor. With an image quality monitor, the imaging performance is monitored. If a decrease in imaging performance is detected especially for a beamlet corresponding to a multi-pole element 87 with voltages supplied by at least two voltage supply units, the voltage correction step is triggered. In a second example, the monitoring step utilizes the signal generated by the voltage drift monitor 835 (see FIGS. 2A-2B). If a representative voltage generated by for example the first voltage supply unit deviates from a predetermined voltage by more than a predetermined threshold, the voltage correction step is triggered and for example a constant voltage offset for the electrodes of a second group of the multipole-element is determined and generated. The predetermined threshold can for example be 1V, 0.5V or even less. The corresponding digital control signals for the control of the second voltage supply unit is subsequently amended to achieve compensating digital control signals. Thereby, the addition of the constant voltage offset values by the second voltage supply unit to the involved electrodes of the second group of electrodes is accomplished. Thereby, the imaging performance of the multi-beam charged particle microscope 1 is maintained even if individual voltage supply units are subject to different voltage drifts.

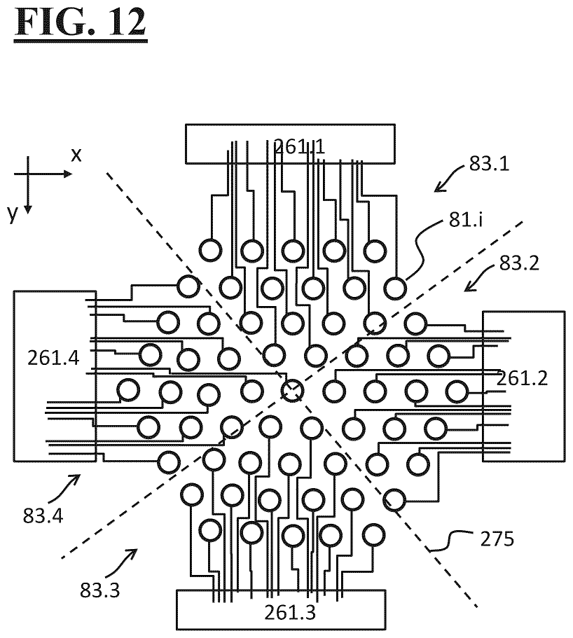

FIG. 12 illustrates an example of an active multi-aperture element 306.1 with a plurality of ring electrodes 81, forming during use a plurality of micro-lenses. In this example, the ring electrodes are grouped in four segments 83.1 to 83.4. The voltages supplied during use are configured to adjust the focus positions of the plurality of primary beamlets 3 in the curved intermediate image surface 321. Thereby, a field curvature of the object irradiation unit 100 is compensated. The voltages are provided to each group or electrodes of a segment by a separate voltage supply unit 261.1 to 261.4. Typical voltages are 100V, but larger voltages of up to 200V are possible. The voltage supply units for micro-lenses are therefore even more sensitive to thermal drifts. If here for example an individual voltage supply unit 261.3 is subject to a drift, for example due to x-ray radiation or thermal drift, the focus points 311 or the primary charged particle beamlets 3 corresponding to segment 83.3 have a constant offset from the intermediate image plane 321 and are out of focus at the object plane 101 of the multi-beam charged particle microscope 1. The voltage drift of a voltage supply unit 261.3 can be detected either by a voltage monitor 835 or by the imaging quality monitor. The beamlets corresponding to segment 83.3 provide a lower resolution during imaging, which can be determined for example by the image quality monitor. The voltage drift of for example the voltage supply unit 261.3 can be compensated by the method described fourth embodiment by providing modified control signals to the voltage supply unit 261.3 or to the voltage supply unit 261.1, 261.2 and 261.4. Thereby, a focusing of the plurality of primary beamlets in a single focus plane is maintained. If this focus plane deviates from the image plane 101, the focus plane can be adjusted by further lens elements of the multi-beam charged particle beam system 1.

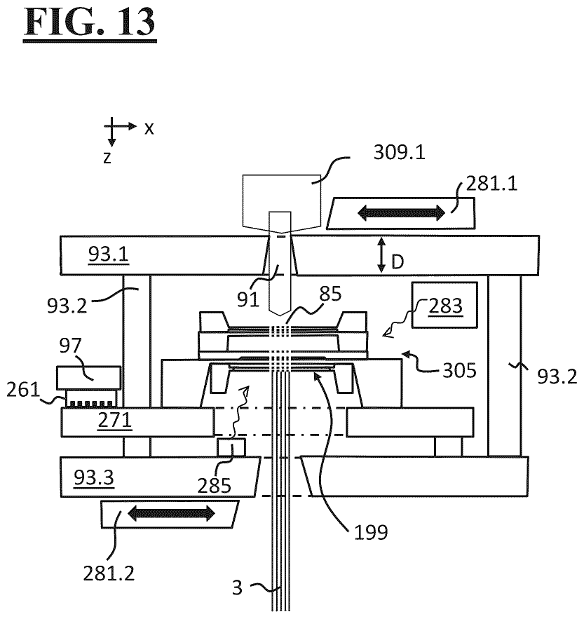

Due to x-ray radiation, not only voltage supply units or ASICs 261, but also the active multi aperture elements 306 of the primary multi-beamlet forming unit 305 can accumulate local damages including local charging effects. The membrane zone 199 of the multi aperture elements are for example formed by doped silicon with isolating layers and features made from silicon dioxide. Interconnections between the electrodes and the voltage supply units or ASICs 261 can be formed by metal layers. For example, X-ray radiation can thus produce local inter-surface defects, for example between silicon and silicon dioxide, and can be responsible for local charging effects, which have an impact on the electrical fields generated by electrodes and thus the performance of active elements. At least a major part of the defects or local charging effects can be annealed by thermal or plasma annealing. FIG. 13 illustrates a further example of an annealing operation. FIG. 13 is similar to FIG. 7 and reference is made to FIG. 7 for the description. In addition to FIG. 7, the shielding plates 93.1 and 93.3 further operate as vacuum valves with slides 281.1 and 281.2. In FIG. 13, both valves are illustrated in open position, however, both valves can be closed by movable slides 281.1 and 281.2. Thereby, a closed and separated vacuum compartment for the primary multi-beamlet forming unit 305 can be generated. The annealing temperatures of about 250° C. and more can be achieved for example via infrared irradiation with irradiation device 285. In an example, annealing is achieved by a low energy plasma of a gas, for example a hydrogen plasma or a nitrogen plasma at about 0.1 mbar. The plasma can be operation by plasma generator 283, with a frequency of for example 13.56 MHz and a low power of about 10 to 20 W. With either or both methods, local defects can at least partially be cured and a lifetime of a multi-aperture element can be extended.

With the solutions provided by the embodiments of the disclosure, a drift of a voltage supply unit 261 can effectively be reduced by a shielding member 93, by a cooling member 97, or by the method of operation of the voltage supply units 261, including the optional application of a voltage monitor 835. It is also possible to implement the combination of the shielding member 93 and the cooling member 97 with the method of operation of an active multi-aperture element. Thereby, effects of voltage drifts can be reduced, and damage of multi-aperture elements and the voltage supply units by x-ray radiation is minimized. Thereby, for example the lifetime of voltage supply units or active multi-aperture elements can be extended. With the annealing methods described above, local charging and local defects can at least partially be reduced or cured and a lifetime of a multi-aperture element or a voltage supply unit can be extended. The up time of a multi-beam charged particle microscope is thus increased and service or maintenance including the replacement of expensive parts is reduced.

### A List of Reference Numbers is Provided:

1 multi-beamlet charged-particle microscopy system
3 primary charged particle beamlets, or plurality of primary charged particle beamlets
5 primary charged particle beam spot
7 object or wafer
9 secondary electron beamlet, forming the plurality of secondary electron beamlets
11 secondary electron beam path
13 primary beam path
15 secondary charged particle image spot
25 Wafer surface
31 vacuum chamber
74 beam entrance or upper side
76 bottom side or beam exiting side
81 multipole electrodes
83 group of electrodes
85 apertures
87 multi-pole element
91 large aperture
93 shielding member
97 cooling member
100 object irradiation unit
101 object plane
102 objective lens
103 field lens group
105 optical axis of multi-beamlet charged-particle microscopy system
108 first beam cross over
110 collective multi-beam raster scanner
197 support zone
199 membrane zone
200 detection unit
205 projection system
206 electrostatic lens
207 image sensor
208 imaging lens
209 imaging lens
210 imaging lens
212 second cross over
214 aperture filter
216 active element
218 third deflection system
220 multi-aperture corrector
222 second deflection system
251 high voltage wiring connection
253 ground line
255 coaxial shielding and isolation
257 low voltage wiring connections
261 voltage supply unit
263 voltage control output
267 digital signal line
269 low voltage supply lines
271 carrier element
273 segment
275 segment border
281 slider of vacuum valve
283 plasma generator
285 infrared source
300 charged-particle multi-beamlet generator
301 charged particle source
303 collimating lenses
304 filter plate
305 primary multi-beamlet forming unit
306 active multi-aperture element
307 first field lens
308 second field lens
309 primary electron beam
310 terminating multi-aperture element
311 primary electron beamlet spots
321 intermediate image surface
390 active or beam steering multi aperture element
400 beam splitter unit
420 correction element
500 sample stage
503 Sample voltage supply
800 control unit
820 imaging control module
830 primary beam-path control module
835 Voltage Drift Monitor
840 Array Control unit
860 Image performance sensor
901 secondary radiation

What is claimed is:

1. A multi-beam system, comprising:
an active multi-aperture element, comprising:
a plurality of apertures in a raster configuration, the plurality of apertures configured to transmit a first plurality of primary charged particle beamlets through the active multi-aperture element;
a plurality of electrodes comprising a first group of electrodes and a second group of electrodes, at least one of the electrodes being in a circumference of each aperture;
a first voltage supply; and
a second voltage supply unit; and
a control unit configured to:
control a plurality of voltages provided by the first voltage supply unit to the first group of electrodes;
control a plurality of voltages provided by the second voltage supply unit to the second group of electrodes; and
compensate a drift of the first voltage supply unit.

2. The multi-beam system of claim 1, wherein the control unit is configured to compensate during use the drift of the first voltage supply unit by a compensating control signal provided to the second voltage supply unit.

3. The multi-beam system of claim 1, wherein the first group of electrodes is in a first angular segment of the raster configuration, and the second group of electrodes is in a second angular segments of the raster configuration which is different from the first angular segment of the raster configuration.

4. The multi-beam system of claim 1, wherein the first group of electrodes is in a first radial segment of the raster configuration, and the second group of electrodes is in a second radial segments of the raster configuration which is different from the first radial segment of the raster configuration.

5. The multi-beam system of claim 1, further comprising a monitoring device configured to monitor the drift of the first voltage supply unit.

6. The multi-beam system of claim 1, wherein the active multi-aperture element comprises a micro lens array comprising a ring electrode at each aperture.

7. The multi-beam system of claim 1, wherein the active multi-aperture element comprises a multi-pole array comprising a plurality of multi-pole elements comprising a number of electrodes at each aperture, the number of electrodes of each multi-pole element being two, four, six, eight or twelve.

8. The multi-beam system of claim 1, further comprising a shielding member configured to shield the first and second voltage supply units from secondary radiation.

9. The multi-beam system of claim 8, wherein the shielding member is between the first and second voltage supply units and a membrane zone of the active multi-aperture element comprising the plurality of apertures.

10. The multi-beam system of claim 8, wherein the first voltage supply unit is between the plurality of apertures, and the shielding member comprises a cap covering the first voltage supply unit.

11. A unit, comprising:
a multi-aperture element comprising a plurality of apertures in a raster configuration, the multi-aperture element configured for transmit a first plurality of primary charged particle beamlets through the active multi-aperture element;
a plurality of electrodes comprising at least one electrode in a circumference each apertures;
a first voltage supply unit configured to provide a plurality of voltages to a group of electrodes of the plurality of electrodes;
a shielding member configured to shield the first voltage supply unit from secondary radiation.

12. The forming unit of claim 11, wherein the first voltage supply unit is adjacent to the plurality of apertures, and the shielding member is between the plurality of apertures and the first voltage supply unit.

13. The unit of claim 12, wherein the shielding member is elongated parallel to a propagation direction of the primary charged particle beamlets.

14. The unit of claim 11, wherein the shielding member is in contact with the first voltage supply unit.

15. The unit of claim 14, wherein the first voltage supply unit is between the plurality of apertures.

16. The unit of claim 11, further comprising a cooling member configured to reduce a thermal drift of the first voltage supply unit.

17. The unit of claim 16, wherein at least one member selected from the group consisting of the shielding member and the cooling member is connected to a thermal sink.

18. The unit of claim 11, wherein the shielding member comprises a material of a first group of materials comprising Molybdenum, Ruthenium, Rhodium, Palladium or Silver.

19. The unit of claim 18, wherein the shielding member has a thickness greater than one millimeter.

20. The unit of claim 11, wherein the shielding member comprises a material selected from the group consisting of tungsten, rhenium, osmium, iridium, platinum, gold and lead.

21. The unit of claim 20, wherein the shielding member has a thickness greater than 100 micrometers.

22. The unit of claim 11, wherein the shielding member is connected to ground level.
